(19) United States
(12) Patent Application Publication
(10) Pub. No.: US 2022/0320854 A1
(43) Pub. Date: Oct. 6, 2022

(54) SMART SHEATH FOR ELECTRIC CABLES, ELECTRICAL EQUIPMENT POWERED BY THE CABLE AND SYSTEM COMPRISING THE EQUIPMENT

(71) Applicant: Paolo VASSALLI, Accadia (IT)

(72) Inventor: Paolo VASSALLI, Accadia (IT)

(21) Appl. No.: 17/640,821

(22) PCT Filed: Sep. 21, 2020
(86) PCT No.: PCT/IB2020/058768

§ 371 Date: Mar. 6, 2022

(30) Foreign Application Priority Data
Sep. 19, 2019 (IT) 102019000016733

(51) Int. Cl. H02H 7/22; G01R 31/58; G01R 31/52; H02G 3/04

(52) U.S. Cl. CPC H02H 7/228; G01R 31/58; G01R 31/52; H02G 3/0462

(57) ABSTRACT

A smart sheath for the protection of an electric cable comprises an inner insulating tubular layer (3) adapted to contain the conductive elements (4) of the electric cable (1), an outer tubular protective layer (5) placed on the inner tubular layer (3), coaxially thereto, an electric control circuit (6) arranged inside the outer tubular layer (5) and adapted to intercept the induced electric currents generated by the passage of the electric current in the conductive elements (4). Furthermore, the electric control circuit (6) is operatively connected to electric current sensor means (7) and to microcontrollers (13) adapted to discriminate a value of the induced electric current higher than a predetermined maximum value to signal an overload inside the electric cable (1) or absence of the induced electric current for report a possible short-circuit.

### TECHNICAL FIELD

The present invention finds application in the field of electric cables and conductors for the passage of electric current and has particularly as its object an intelligent sheath for the protection of electric cables suitable for signalling possible states of electric overload and/or possible short circuits.

The invention also relates to an electrical and/or electronic equipment powered by at least one electric cable provided with the above sheath.

The invention also relates to a system for the control of one or more of such equipment.

### STATE OF THE ART

As known, common electric cables are generally devoid of systems integrated thereinside that allow to perceive the overload currents inside the electric cables themselves and/or to prevent the generation of short-circuit currents that could create damage to the cable itself, to the equipment connected thereto and could cause fires. Currently, to perceive the overload inside an electric cable, there are some proven solutions, such as current transformers and the like.

On the contrary, there is no solution that prevents the generation of short-circuit currents due, for example, to damage to the sheath of the electric cable which could cause contact between two electric current conductors characterized by different voltage values.

Furthermore, all switching devices currently on the market only intervene when the short circuit has already occurred, avoiding preventive action from being taken, for example by disconnecting the equipment powered by the damaged electric cable or replacing the damaged electric cable or reducing the electrical load in case of overloads.

In particular, some switchgear existing on the market, such as disconnectors, switchgear, IMS, contactors and fuses, are unable to open and/or close an electrical circuit under overload conditions (healthy circuit) and/or short circuit (damaged circuit).

US2018/231595 discloses a system for the control of damage inside electrical cables and which could lead to short circuits.

This system describes a cable provided with an outer protective sheath in one or more layers which contains thereinside a pair of electric power supply cables each having its own filiform conductive element wrapped in its own inner sheath.

A further sensing element is inserted inside the outer sheath to place itself between the two power cables and intercept the induced electric currents that are generated by the law of electromagnetic induction following the passage of current in the power cables. The detection element is connected to a unit of measurement which evaluates whether the detected value of the induced current remains below a limit value or if it exceeds this value, symptom of possible damage to one of the cables, consequently interrupting the power supply.

However, the arrangement of the sensing element inside the outer sheath, and therefore outside the two power cables, does not allow to accurately and immediately detect the innermost damage to the internal sheaths of the two power cables, with the risk that the unit of measurement intervenes too late, i.e. when the cable is irreparably damaged. As matter of fact, the electromagnetic flux and electromagnetic energy generated by an electric cable/source of electromagnetic waves are attenuated according to the distance from the source itself. Furthermore, the detection time depends on the distance of the electromagnetic source.

Furthermore, the arrangement of the sensing element inside the outer sheath implies that this solution can be used mainly for industrial applications, or for three-phase, high voltage electrical systems.

On the contrary, the solution described in US2018/231595 will find it difficult if not impossible to apply in single-phase electrical systems, typical in residential homes with an electrical power of 3 kw, wherein the electrical cables that power single-phase electrical loads generate values of intensity of the induced electrical current from individual electrical cables less than 4*10-5 A (average value).

The solution described in US2018/231595 is difficult to implement in single-phase electrical systems also due to its bulky size which makes it difficult, perhaps impossible, to position the device in the junction boxes of single-phase electrical systems.

Furthermore, it has high maintenance and repair costs also due to the numerous components subject to obsolescence of which it is composed.

Furthermore, the solution described in US2018/231595 assumes, in the design and operation phase thereof, the formation of any sparks or electric arcs that could be triggered between two electrical contacts, or between the power supply wire and the electrical shield or between two wires and therefore provides for the installation of an optically conductive detector to detect such sparks/electric arcs.

### Scope of the Invention

The object of the present invention is to overcome the above drawbacks by providing a smart sheath for the protection of an electric cable capable of perceiving the overload currents inside the electric cable and of preventing the generation of short-circuit currents in order to preserve the integrity of the sheath itself as well as of the circuit.

A particular object is to provide a smart sheath which allows such currents to be detected in a particularly rapid and effective manner.

A particular object is to provide a smart sheath that allows to send information in real time regarding any overloads affecting the relative electrical cable or any short-circuits that may occur, in order to allow immediate intervention on the electric cable and on the corresponding electric load, to reduce it or to interrupt the power supply.

Still another object of the present invention is to make available an electrical or electronic equipment powered by an electric cable provided with the above sheath and which can be easily controlled according to the signals coming from the sheath in order to regulate the load or interrupt the power supply and prevent possible damage thereto.

Still another object is to provide a system for the control of one or more of these equipment which allows the transmission in real time of information relative to possible overloads and/or the occurrence of eventual short-circuits affecting one or more power supply electric cables to allow prompt intervention, even at a distance, to avoid serious damage to equipment and/or electrical cables, as well as general risks associated with possible fires.

These objects, as well as others that will become more apparent hereinafter, are achieved by a smart sheath for the protection of electric cables which, according to claim 1, comprises an inner insulating tubular layer suitable for containing the conductive elements of the electric cable, an outer tubular protective layer placed on said inner layer and coaxially thereto, an electric control circuit placed inside said outer tubular layer and adapted to intercept the induced electric currents generated by the passage of the electric current in the electric cable, said electric control circuit being also operatively connected to electric current sensor means adapted to discriminate a value of the induced electric current higher than a predetermined maximum value to signal an overload inside the electric cable or the absence of said induced electric current to signal a possible short-circuit.

Thanks to this combination of features, the sheath will be adapted to immediately detect any overloads and/or prevent possible short-circuits affecting the corresponding electric cable in order to immediately report such occurrence to allow immediate intervention.

Advantageously, the sheath may comprise a local control logic unit adapted to send without delay the values of the induced electric current intensity detected by said sensor means to an external control unit, via cable or wirelessly.

In this way, it will be possible to integrate the sheath and consequently the equipment powered by the cable provided with the sheath within smart home automation or IoT systems in order to allow continuous monitoring of the correct functioning of the equipment and allow rapid and effective interventions, possibly even remotely.

Conveniently, said electric current sensor means may comprise a high-precision digital galvanometer adapted to read values of the electric current intensity lower than 4*10-5 A, i.e. values falling within the range of safety values since they are below the perception threshold, so as to increase safety.

According to a further aspect of the invention, an electrical and/or electronic apparatus is provided which, according to claim 8, is powered by at least one electric cable wrapped in an intelligent sheath according to the invention, so as to allow a user to intervene on the equipment itself in a timely manner and before particularly serious damage can occur.

According to yet another aspect of the invention, a system is provided for the control of electrical and/or electronic equipment in accordance with claim 9, to which reference should be made for seeking of conciseness of the explanation.

The system configured in this way will allow to constantly monitor various equipment in order to intervene thereon in real time in the event of faults, possibly even remotely, reporting the anomalies to the respective users as well as to other operators, including for example subjects assigned to safety operations or prevention and allowing to have memory of all the faults that have occurred, also for statistical purposes.

Last but not least, the object of the present invention, as a design and operating hypothesis, does not consider the ignition of sparks/electric arcs and the installation of an optically conductive detector to detect them, since sparks/electric arcs can never be triggered between the terminals of the electrical control circuit as they are electrically connected to each other, therefore increasing the simplicity/technical refinement of the invention, economy and above all increasing safety.

Advantageous embodiments of the invention are obtained in accordance with the dependent claims.

### BRIEF DISCLOSURE OF THE DRAWINGS

Further features and advantages of the invention will become more evident in the light of the detailed description of preferred but not exclusive embodiments of a sheath, of an apparatus and of a system according to the invention, illustrated by way of non-limiting example with the aid of the attached drawings, wherein:

FIG. 1 is a perspective view of an electric cable provided with the sheath according to the invention;

FIG. 2 is a front view of the electric cable of FIG. 1;

FIG. 3 is a perspective view of the electric cable of FIG. 1 without the outer tubular layer;

FIG. 4 is a side view of the electric cable of FIG. 1;

FIG. 5 is a rear view of the electric cable of FIG. 1;

FIG. 6 is a side view of the two spiral-shaped electrical conductors;

FIG. 7 is a perspective view of the electrical connection element of the two spiral-shaped electrical conductors;

FIG. 8 shows a possible network architecture for the system according to the invention;

FIG. 9 shows a possible operating mode of the system in the event of an overload;

FIG. 10 shows a possible operating mode of the system in the event of a short circuit.

### BEST MODES OF CARRYING OUT THE INVENTION

With reference to the attached figures, a preferred but not exclusive configuration of an electric cable provided with the smart sheath according to the invention is illustrated.

In particular, the electric cable may already be produced with the smart sheath to replace the common insulating sheath.

Furthermore, the electric cable may also be used to define a single-phase connection provided with a neutral cable (N) and a phase (F).

By way of not limiting example, considering a single-phase electric line in which the phase (F) and neutral (N) cable supply a single-phase load, the electric cable provided with the intelligent sheath according to the present invention may constitute the neutral cable (N) or the phase cable (F) or both the neutral and the phase cables may be provided with the smart sheath according to the present invention.

However, it is understood that an electric cable equipped with a smart sheath may be inserted within any electrical connection, for example of the three-phase type, without particular theoretical limitations.

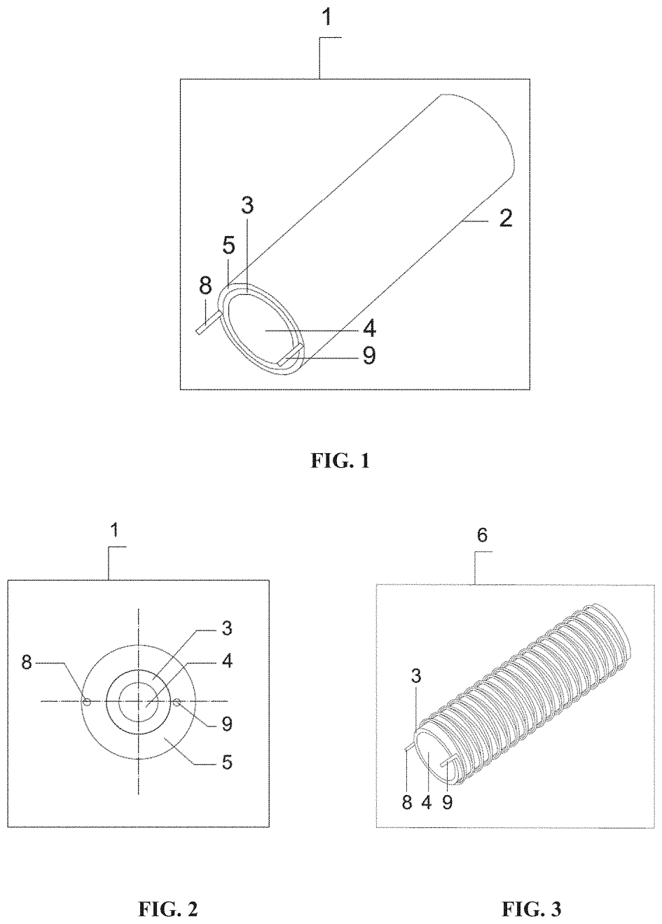

In its more general form illustrated in FIG. 1, the electric cable, globally indicated with 1, will comprise a smart sheath 2 which is essentially composed of an inner tubular insulation layer 3, suitable for containing the conductor element 4 of the electric cable 1, and an outer tubular protective layer 5 placed on the inner layer 3, coaxially thereto. The conductor element 4 may be both of the rigid single-wire and multi-wire type and may be made of any conductive material commonly used in the sector, such as copper, silver or similar.

The two tubular layers 3, 5 will be suitably made of polymeric material with adequate insulation, for example PVC, and suitably sized also according to the electric currents that will circulate in the cable.

In a peculiar way, inside the outer tubular layer 5 an electric control circuit 6 will be arranged to intercept the induced electric currents generated according to the law of electromagnetic induction (Faraday—Neumann—Lenz law) as a consequence of the passage of electric current in the conductor element 4.

The electric control circuit 6 will in turn be electrically connected to electric current sensor means 7 adapted to discriminate a value of the induced electric current higher than a predetermined maximum value and which will also depend on the design electric current values which are expected to circulate in the cable 1.

The electric current sensor means 7 will have the task of signaling any overload or the absence of induced electric current, a sign of a potential short circuit, so as to immediately make this malfunction evident.

According to a preferred but not exclusive configuration, the electric control circuit 6 will comprise a pair of spiral-shaped electric conductors 8, 9 in reciprocal electrical connection and which extend inside the outer tubular layer 5 along the axial development of the tubular layers 3, 5, substantially for the entire length of the electric cable 1, as shown in FIG. 3.

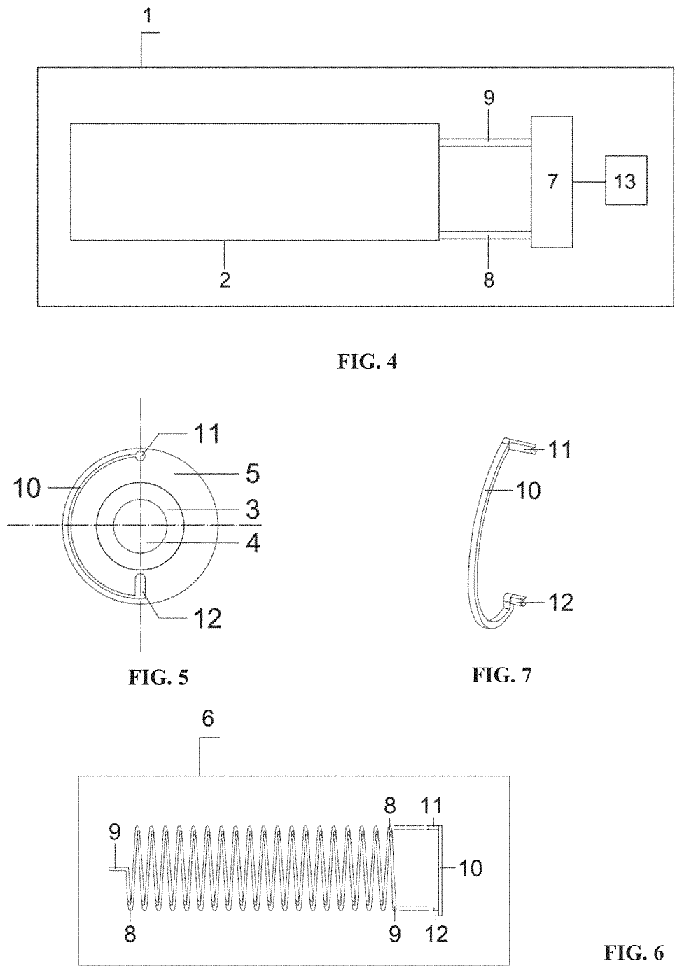

As can be seen from FIG. 4, each of the electric conductors 8, 9 will have a respective terminal which projects from one of the ends of the sheath 2 to be electrically connected to the electric current sensor means 7.

By way of a not limiting example, the electrical conductors 8, 9 will be copper wires or other metal conducting electricity, possibly of a different color so that they may be easily distinguished from each other.

The electric conductors 8, 9 will define the induced electric circuit and will be spirally wound inside the outer tubular protective layer 5, coaxially with each other and with the tubular layers 3, 5 themselves, and will be placed in mutual electrical connection by means of an element of electrical connection 10, also made of copper or other electrically conductive material, connected to both electrical conductors 8, 9.

According to a preferred configuration illustrated in FIGS. 5, 6 and 7, the electrical connection element 10 will be defined by an arcuate body adapted to be positioned on the outer tubular layer 5, in contact therewith, and having ends 11, 12 snap-coupled by means of slight pressure to the respective conductive spiral-shaped electric cables 8, 9.

The operation of applying the electrical connection element 10 may be carried out just by cutting the electrical cable 1 according to a transverse plane for a multiple length of 1 mm, in the case of an electrical cable equipped with a smart sheath installed in a single-phase electrical system, while greater than 1 mm for three-phase electrical systems.

To this end, the outer tubular layer 5 may be provided with a graduated scale designed to define a reference for the operator.

Conveniently, the sensor means 7 will comprise an electric current sensor, for example a high precision digital galvanometer, adapted to read values of the electric current intensity lower than 4*10-5 A and connected to the terminals of the spiral-shaped electric conductors 8, 9, so that they may also be used for single-phase electrical systems.

The current sensor 7 is in turn connected to a local control logic unit 13 adapted to collect the values of the intensity of the induced electric current detected by the same sensor 7 and to send them via cable or wirelessly to a centralized control unit external. Preferably, the local control unit 13 may be or comprise a microcontroller having computational capability, equipped with a control board and integrated Wi-Fi chip. The microcontroller 13 and the electric current sensor 7 may be installed either outside or inside the room where the electrical and/or electronic equipment to be powered is present.

In addition, they may be powered by renewable energy sources or, if the microcontroller 13 and the electric current sensor 7 require a very low intensity of electric current for their operation, they could be electrically powered directly by the electric currents induced by the inductor circuit.

An electric or electronic device powered by at least one electric cable 1 wrapped in a smart sheath 2 according to the invention may be any device, both for civil and industrial use, such as, but not limited to, a common household appliance, an electronic device, such as a PC or similar, an electric current generator, an electric motor, a medical device.

For example, the cable 1 provided with the smart sheath 2 could be used to transport the electrical energy necessary to power an expensive medical device for which the phase of monitoring the intensity of the electric current inside the electrical cable, and therefore of the temperature values reached therein, are indispensable requirements. Furthermore, the cable 1 could be used to power medical devices designed to support vital functions and which according to the known art are equipped with systems designed to prevent the generation of short-circuit currents and to open the electrical circuit to stop the medical device.

With the installation of the cable 1 equipped with the smart sheath 2 in the electrical supply system, the probability of not opening the electric circuit in the event of a short circuit would increase, because the cable 1 would intervene before a high overload and/or a short circuit occurs, notifying the person responsible for the operation of the device and its electrical system.

In addition, the cable 1 could be used in electrical systems located in potentially explosive atmospheres. In such environments a probable short circuit and/or overload could trigger a fire or an explosion.

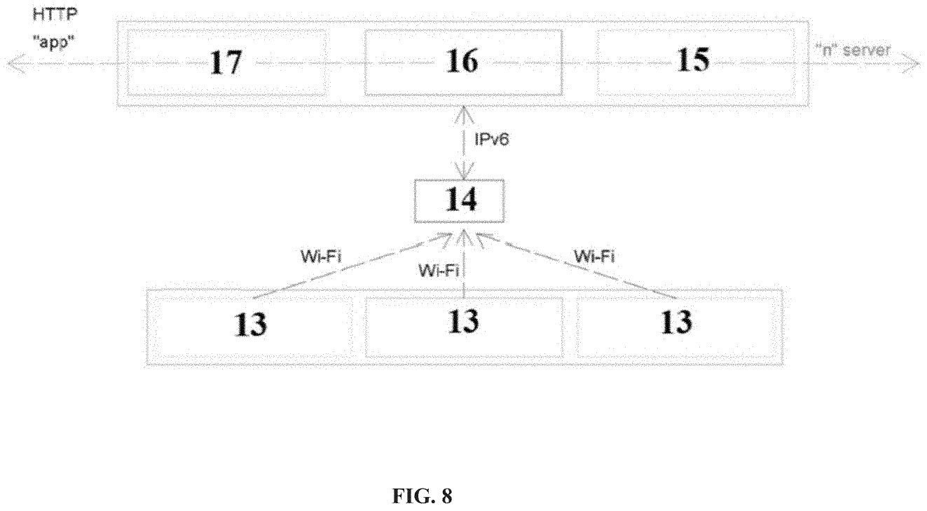

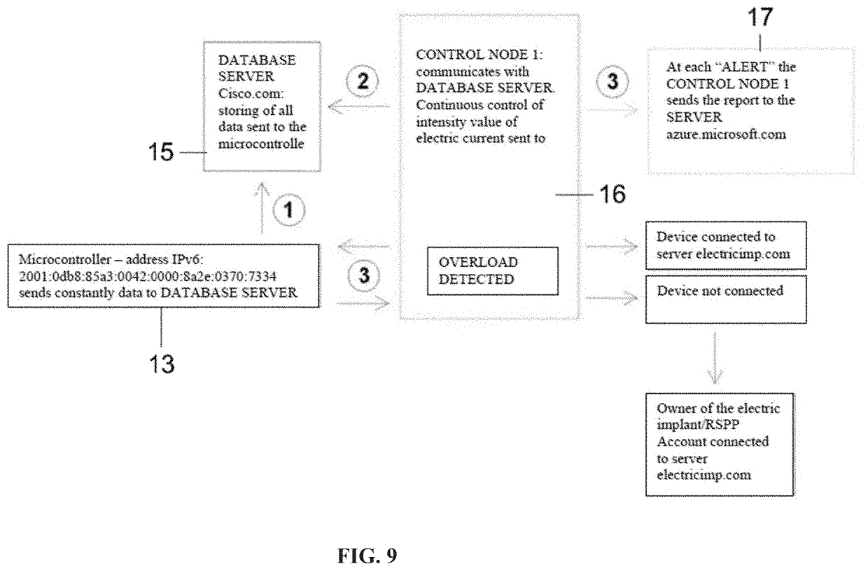

The electrical or electronic equipment powered by electric cables 1 each provided with a respective smart sheath 2 may be inserted inside a system for the control of electrical and/or electronic equipment comprising a plurality of electrical and/or electronic equipment, one or more of which may be powered by respective electric cables 1 provided with smart sheaths 2 as described above and provided with electric current sensor means 7 and with a respective local control logic unit or microcontroller 13. The system, schematized in FIG. 8, comprises a central control unit 14 connected via cable and/or wirelessly to the local control units 13 of the various sheaths 2 to constantly receive the induced electric current values detected by the corresponding electrical current sensor means 7 and report any overloads and/or potential short circuits to one or more users.

The central control unit 14 comprises a first server 15 having a database function and adapted to store the values of the intensity of the induced electric current sent by the local control units 13 and a second server 16 adapted to communicate with the first server 15 for continuously check the values of the intensity of the induced electric current and compare them with predetermined values stored therein.

The second server 16, through the local control units or microcontrollers 13, is in turn adapted to signal to the user responsible for a certain equipment of any overload generated in one of the electrical cables 1 and/or a probable short circuit.

Furthermore, in the case of intelligent equipment, that is suitable for being connected to the internet network and equipped with its own load regulation and/or power supply control system, it will be possible to send a command to the equipment itself in order to reduce load or stop the equipment itself before the corresponding sheath is damaged 2.

The central control unit 14 may also comprise a third server 17 adapted to store all the alert signals sent by the second server 16, so as to keep track of all the episodes that have occurred.

The communication between users and the central unit 14 may take place through specific applications, so as to increase safety and prevention.

By way of example, if one of the microcontrollers 13 of one of the sheaths 2 detects a high overload inside the corresponding electric cable 1 and the user responsible for the corresponding equipment does not intervene within a predefined time limit, before the sheath melts 2 and a short circuit occurs, therefore a probable fire, the microcontroller 13 will be adapted to warn in good time other operators assigned to safety, such as the Fire Brigade and/or the Municipal Police, in order to facilitate any rescue operations. It will also be possible to send a report to the supervisory bodies, who may subsequently carry out a check on the electrical system in order to avoid or reduce the risk of new events in the future.

A further particularly advantageous application of the system may find its place in complex electricity distribution systems, such as those within a nuclear power plant or within a large industrial complex.

Such an electrical system is, in fact, made up of a dense network of electrical cables up to tens and tens of meters long.

In this case, the initiation of a phenomenon that could damage the sheath of one of the electric cables of the dense network of electric cables could create problems, such as short circuits, high overloads, fires, production stops, whose resolution would involve times and considerable economic charges.

Currently it is difficult if not impossible to trace the specific overloaded electric cable and/or with the damaged sheath.

On the contrary, a system in which the electrical cables 1 are provided with the sheath 2 according to the invention and are connected to the above central control unit 14 would allow to overcome these drawbacks.

As matter of fact, by designing a layout of the location of each microcontroller 13 within the electrical system, it will be possible to easily trace each electrical cable 1, which will be appropriately coded, for example via an IPv6 address.

It should be noted that the overload condition inside the electric cables is very frequent and is often not caused by the mere fact that an intensity of electric current greater than its capacity circulates inside the electric cable.

As matter of fact, in some electrical systems, especially on construction sites and in domestic electrical systems, new electrical cables are often added to others already existing in the same installation duct. The situation that is encountered is the arrangement of the electrical cables very close to each other (overlapping) with the consequent increase in the temperature inside them (overload) under normal operating conditions of the electrical system.

An application of the system object of the invention in such contexts could avoid these inconveniences caused by a lack of culture about electricity.

Below there is an example of possible application of the sheath 2 and of a system comprising one or more electrical devices powered by electric cables 1 comprising the above sheath 2.

All the data shown will refer to a 5 m long electric cable 1 with a section of 1.5 mm2 Consider a single-phase line with a transformer and wherein a phase cable and a neutral power a single-phase load that absorbs 1800 W and is located inside a house, mains voltage of 230V and frequency of 50 Hz.

It is assumed that only the phase conductor is provided with the sheath 2 according to the invention, it being understood, however, that the neutral conductor could also be provided therewith.

In this hypothesis, it is possible to calculate that to power the single-phase electrical load, an electric current intensity of 7.83 A is required. It has also been calculated that by choosing a cable with section S=1.5 mm2, i.e. with a section typical of commercial and therefore economical cables, the integrity of the insulating sheath 2 is guaranteed, i.e. its maximum allowable temperature is not exceeded (70° C. for PVC).

The value I=7.83 A is the maximum value that the electric current intensity can reach under normal conditions. If inside the electric cable 1 there was an electric current intensity greater than 7.83 A, overload would occur.

Considering the maximum value that the intensity of electric current can reach in the electrical system under examination (I=7.83 A) it was also possible to calculate the electric currents induced in the two spiral-shaped copper conductors 8, 9 placed inside the outer tubular layer 5.

In particular, it was determined that in the spiral-shaped electric conductor 8 the induced electric current has a value of 5.4*10-5 A, while for the other spiral-shaped electric conductor 9 the value is 3.9*10-5 A.

Therefore, in case of overload, the total induced electric current intensity in the inductor circuit 6 will assume a value equal to 0.000094 A (>0.000093 A).

Considering these induced electric currents in normal operating conditions, powering a single 1800 W load, the two sections of 0.13 mm2 for the two spiral-shaped copper electrical conductors 8, 9 occurred.

With these sections, the two spiral-shaped copper electrical conductors 8, 9 may transport an electric current of greater intensity than that induced by the inductor circuit under full load conditions.

It should be noted that the intensity of the electric currents induced in the two spiral-shaped copper conductors 8, 9 are of the order of 10-5 A, even in the event of overload.

The two electrical conductors 8, 9, if crossed by an electric current, will never constitute a danger to humans.

In the event that the sheath 2 or the outer tubular layer 5 which comprises the two copper electrical conductors 8, 9 in tension were perforated or sheared in such a way as to create a direct contact, the induced electric current will not be perceptible by man.

The sheath 2 or the electric control circuit 6 may be connected to a microcontroller 13 with a predefined IPv6 address to which an electric current sensor 7 is connected which measures the values of the total induced electric current intensity in the two copper electric conductors a spiral shape 8, 9.

When the electric current circulates inside the phase 4 conductor to power the load, due to the aforementioned law of electromagnetic induction, induced electric currents will circulate inside the induced circuit 6 placed inside the outer tubular layer 5.

By measuring these induced electric currents, the sensor means 7 will be able to perceive any overload inside the electric cable 1 and prevent the generation of short circuit currents in the event that the sheath 2 or the outer tubular layer 5 is damaged. More precisely, the microcontroller 13 equipped with an integrated Wi-Fi chip allows to send the values of the total intensity of the induced electric current read by the sensor 7 constantly and without delay to the first database server 15, which in turn stores them.

Preferably, the microcontroller 13 and the sensor 7 will be a single component, so as to eliminate any delay in sending data and make the device even faster and more effective.

The second server 16 operating as a control node communicates with the first server 15 and continuously monitors the values of the total induced electric current intensity and only in two cases, namely overload and potential short circuit, communicates with the microcontroller 13.

As soon as, checking the values, it detects the value 0.000094 A (in case of overload), the second server 16 communicates it to the microcontroller 13 which can carry out one of the following two operations:
if the equipment is connected to the microcontroller 13, or it is “smart”, it will issue the command to decrease the load or stop the equipment that caused the overload;
if the equipment causing the overload is not connected to the microcontroller 13, for example in the case of traditional non-smart equipment, it will send an alarm signal, for example via SMS, via an application to the owner of the system or to the responsible of the safety, informing him that the overload has occurred, so as to indicate the need to reduce the load or stop the equipment.

The third server 17 stores all the alarm signals received by the second server 16 in case of overload and/or potential short-circuit.

When the electric current sensor 7 reads no value (OA) it means that one of the two copper electrical conductors 8, 9 has been damaged or that both have been damaged at the same time.

If the two electrical conductors 8, 9 have been damaged, it means that the outer layer 5 of the sheath 2 has also been damaged and therefore a short-circuit could occur between two adjacent electrical cables characterized by different voltage values.

In this case, if the second server 16 detects the value 0.000000 A (sheath damaged) it communicates it to the microcontroller 13 which sends an alarm signal via an application to the owner of the system or to the safety manager, warning him that a short-circuit could occurr.

The owner of the microcontroller 13, or the operator responsible for controlling the system, for example in the case of a public structure wherein the sheath is installed, will register himself and the microcontroller 13 on the three servers 15, 16, 17, or on three corresponding websites.

In this way the microcontroller 13 will be associated with a unique IPv6 address as well as the owner will be associated with a unique code. The owner may connect other “node” microcontrollers to the three servers 15, 16, 17, as well as other equipment owners may connect to the three servers 15, 16, 17 and add other microcontrollers. The resulting system will thus be defined by a network of “nodes”.

Each user may program their respective microcontrollers 13 using a predefined programming language, by way of example Squirrel, and will download three applications from the three above websites on their device in order to connect, using the HTTP communication protocol, their own microcontrollers 13 to the three servers 15, 16, 17 and the three servers 15, 16, 17 with each other.

In this way the sheath 2 provided with a microcontroller 13 with computational capacity and connected to the servers 15, 16, 17 will become an object of the IoT (Internet of Things), ready to communicate through applications with other IoT objects and with humans, such as shown in the diagram of the same FIG. 8.

Logically, by connecting the microcontroller 13 to other servers, the functions of the smart sheath 2 may be increased, such as for example a self-learning function (“machine learning”).

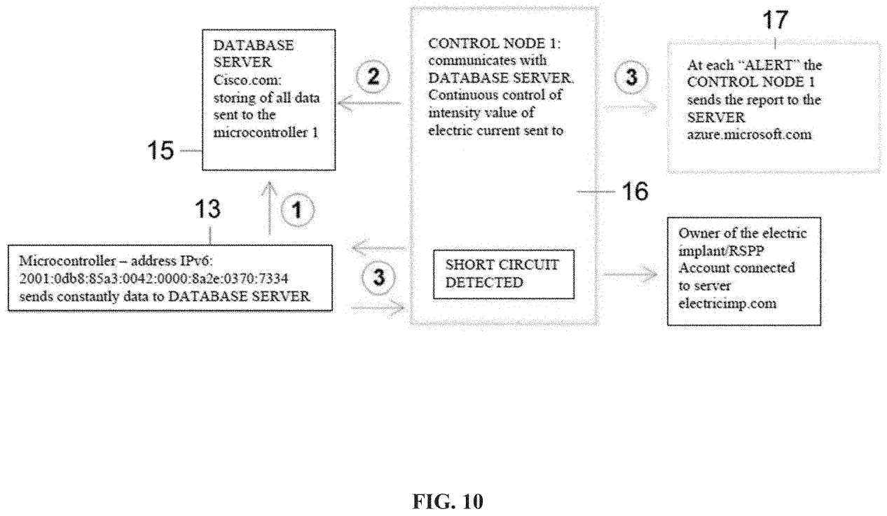

FIG. 9 shows the network architecture designed for the system in the event of an overload while FIG. 10 shows the network architecture designed for the system in the event of a potential short-circuit.

Note that, both in the event of an overload and a potential short-circuit, the second server 16 which acts as a control node, in addition to communicate with the microcontroller 13, also communicates with the third server 17.

This server stores:
the IPv6 address of the microcontroller 13 that detected the overload and/or potential short-circuit;
the account connected to the second server 16;
the code of the house where the microcontroller 13 is installed;
all parameters relating to the electrical system in which the microcontroller 13 is installed (frequency, voltage, etc.) and the date of the declaration of conformity of the electrical system with the name of the qualified technician who signed it;
the time when the “alert” occurred;
the value of the total induced electric current associated with the overload and the section of the electric cable 1;
the names and registered offices of the manufacturers of the sheath 2 and of the two spiral-shaped copper electrical conductors 8, 9.

The system, if installed in a domestic or industrial electrical system, in addition to perceiving the overload currents and preventing the generation of short-circuit currents with the use of a single electric current sensor, has other peculiarities and further advantages.

First of all, it allows to increase the useful life of the switching devices because it reduces the number of times they should intervene: as matter of fact, each switching device when it is activated to interrupt and/or establish an electric current always suffers a “damage”, slight or severe (think to the fuse element of the fuse).

The number of electric arcs caused by the opening of the switches decreases as the number of times the switch will trip will decrease.

According to the “Arrenhius law”, the useful life of the insulation and the sheath of the electrical cable would increase.

Furthermore, the system would intervene before a high or dangerous overload and/or a short-circuit or a probable fire occurs, increasing safety.

Furthermore, other users may connect to the third server 17, through suitable applications, with the authorization of the owner or of the security manager of the microcontroller 13 connected to the above server 17.

In this way, two data streams are generated:
a vertical flow between the manufacturers of the conductor, the insulation, the sheath and the spiral-shaped copper elements and the third server, in order to extrapolate data for use in research and development studies to improve the efficiency and productivity of products or experimenting with new products on the basis of any errors made, improving their construction quality and their performance;
a horizontal flow between some public/private bodies and the third server 17, for example in order to perform statistical analysis on the number of “alerts” detected with respect to the number of IoT microcontrollers installed in electrical systems; in this way it would be possible to study the geographical areas in which the greatest number of “alerts” occurred, or to establish a program of checks to be carried out periodically on the electrical systems based on the history of checks/inspections reported on the third server 17; last but not least, it would be possible to carry out checks on some parts of the electrical system more deeply or carry out a predictive analysis on possible new “alerts” that may occur.

The sheath, the equipment and the system according to the invention are susceptible of numerous modifications and variations, all falling within the inventive concept expressed in the attached claims. All the details may be replaced by other technically equivalent elements, and the materials and tools may be different according to the requirements, without departing from the scope of protection of the present invention.

1. A smart sheath for the protection of an electric cable, wherein an electric cable (1) comprises one or more conductive elements (4) adapted to allow the passage of an electric current, which sheath comprises:
an inner insulating tubular layer (3) adapted to contain the conductive elements (4) of the electric cable (1);
an outer tubular protective layer (5) placed on said inner tubular layer (3), coaxially thereto;
an electric control circuit (6) arranged inside said outer tubular layer (5) and adapted to intercept the induced electric currents generated by the passage of the electric current in the conductive elements (4),
electric current sensor means (7) operatively connected to said electric control circuit (6) and adapted to discriminate a value of the induced electric current higher than a predetermined maximum value to signal an overload inside the electric cable or absence of said induced electric current for report a possible short-circuit.
characterized in that said electric control circuit (6) comprises at least one pair of electrical conductors (8, 9) in reciprocal electrical connection placed inside said outer tubular protective layer (5) and which extend along the axial extension of said tubulars layers (3, 5) and having respective terminals electrically connected to said electric current sensor means (7).

2. Sheath as claimed in claim 1, characterized in that said electrical conductors (8, 9) are spiral-shaped.

3. Sheath as claimed in claim 2, characterized in that said electrical conductors (8, 9) are wound in a spiral around said inner tubular layer (3) and are coaxial to each other and to said tubular layers (3, 5).

4. Sheath as claimed in claim 2 or 3, characterized in that said electric control circuit (6) comprises at least one electrical connection element (10) connected to both said electrical conductors (8, 9) for the mutual electrical connection therebetween.

5. Sheath as claimed in claim 4, characterized in that said at least one connection element (10) comprises an arched body arranged on said outer tubular layer (5) and having ends (11, 12) snap-coupled to respective of said spiral-shaped electrical conductors (8, 9).

6. Sheath as claimed in claim 1, characterized by comprising a local control logic unit or microcontroller (13) adapted to send without delay the values of the intensity of the induced electric current sensed by said electric current sensor means (7) to an external control unit (14), by cable or wirelessly.

7. Sheath as claimed in claim 6, characterized in that said electric current sensor means (7) comprise a high-precision digital galvanometer suitable for reading values of the electric current intensity less than 4*10⁻⁵ A and connected to said terminals of said electric current sensor means (7).

8. An electric or electronic equipment powered by at least one electric cable (1) wrapped in a smart sheath (2) according to claim 1.

9. A system for the control of electric and/or electronic equipment comprising one or more electrical and/or electronic devices, one or more of which is powered by one or more electric cables (1) wrapped in respective smart sheaths (2), wherein each of said smart sheaths (2) comprises:
an inner insulating tubular layer (3) adapted to contain the conductive elements (4) of the electric cable (1);
an outer tubular protective layer (5) arranged on said inner tubular layer (3), coaxially thereto;
an electrical control circuit (6) placed inside said outer tubular layer (5) and adapted to intercept the induced electric currents generated by the passage of the current in the conductive elements (4);
electric current sensor means (7) operatively connected to said electric control circuit (6) and adapted to discriminate a value of the induced electric current higher than a predetermined value to signal an overload inside the respective of said electric cables (1), or absence of said induced electric current to signal a possible short circuit for the respective of said electric cables (1);
a local control logic unit or microcontroller (13) connected to said electric current sensor means (7) and adapted to collect the values of the intensity of the induced electric current detected by said electric current sensor means (7);
wherein said system comprises a central control unit (14) connected by cable and/or in wireless mode to said local control units (13) of said sheaths (2) to constantly receive the electric current values sensed by the corresponding electric current sensor means (7) and signal any overloads and/or short-circuits to one or more users.

10. System ad claimed in claim 9, characterized in that said central control unit (14) comprises a first server (15) adapted to store the values of the intensity of the induced electric current sent by said local control units (13).

11. System ad claimed in claim 10, characterized in that said central control unit (14) comprises a second server (16) adapted to communicate with said first server (15) to continuously monitor the values of the intensity of the induced electric current and compare them with predetermined values stored therein.

12. System ad claimed in claim 11, characterized in that said second server (16) is adapted to signal to a user, via said microcontroller (13), a possible overload and/or probable short-circuit and to send a command to the equipment provided with said smart sheath (2) for which the detected values are higher than the respective maximum values or are null, for the reduction of the load or the stopping of the equipment itself.

13. System ad claimed in claim 12, characterized in that said central control unit (14) comprises a third server (17) adapted for storing all the alert signals sent by said second server (16).
